(19) United States
(12) Patent Application Publication
(10) Pub. No.: US 2016/0005871 A1
(43) Pub. Date: Jan. 7, 2016

(54) SEMICONDUCTOR DEVICE

(71) Applicant: Semiconductor Energy Laboratory Co., Ltd., Atsugi-shi (JP)

(72) Inventors: Shinpei MATSUDA, Atsugi (JP); Toshihiko TAKEUCHI, Isehara (JP); Daisuke MATSUBAYASHI, Ebina (JP)

(21) Appl. No.: 14/753,426

(22) Filed: Jun. 29, 2015

(30) Foreign Application Priority Data
Jul. 4, 2014 (JP) 2014-139002

(51) Int. Cl. H01L 29/786

(52) U.S. Cl. CPC H01L 29/7869

(57) ABSTRACT

A transistor with a small subthreshold swing value is provided. A transistor with a low density of shallow interface states at an interface between a semiconductor and a gate insulator is provided. A transistor with favorable electrical characteristics is provided. A semiconductor device includes an insulator, a semiconductor, and a conductor. The semiconductor includes a region in which the semiconductor and the conductor overlap each other with the insulator positioned therebetween, and the density of shallow interface states at an interface between the semiconductor and the insulator in the region is lower than or equal to 1×10¹³ cm⁻².

### BACKGROUND OF THE INVENTION

1. Field of the Invention

The present invention relates to, for example, an oxide, a transistor, a semiconductor device, and manufacturing methods thereof. The present invention relates to, for example, an oxide, a display device, a light-emitting device, a lighting device, a power storage device, a memory device, a processor, or an electronic device. The present invention relates to a manufacturing method of an oxide, a display device, a liquid crystal display device, a light-emitting device, a memory device, or an electronic device. The present invention relates to a driving method of a semiconductor device, a display device, a liquid crystal display device, a light-emitting device, a memory device, or an electronic device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter.

In this specification and the like, a semiconductor device generally means a device that can function by utilizing semiconductor characteristics. A display device, a light-emitting device, a lighting device, an electro-optical device, a semiconductor circuit, and an electronic device include a semiconductor device in some cases.

2. Description of the Related Art

A technique for forming a transistor by using a semiconductor over a substrate having an insulating surface has attracted attention. The transistor is applied to a wide range of semiconductor devices such as an integrated circuit and a display device. Silicon is known as a semiconductor applicable to a transistor.

As silicon which is used as a semiconductor of a transistor, either amorphous silicon or polycrystalline silicon is used depending on the purpose. For example, in the case of a transistor included in a large display device, it is preferable to use amorphous silicon, which can be used to form a film on a large substrate with the established technique. On the other hand, in the case of a transistor included in a high-performance display device where a driver circuit and a pixel circuit are formed over the same substrate, it is preferable to use polycrystalline silicon, which can be used to form a transistor having a high field-effect mobility. As a method for forming polycrystalline silicon, a method of performing high-temperature heat treatment or laser light treatment on amorphous silicon has been known.

Recently, a transistor which includes an amorphous oxide semiconductor and a transistor which includes an amorphous oxide semiconductor containing a microcrystal have been disclosed (see Patent Document 1). An oxide semiconductor can be formed by a sputtering method or the like, and thus can be used for a semiconductor of a transistor in a large display device. Because a transistor including an oxide semiconductor has high field-effect mobility, a high-performance display device in which, for example, a driver circuit and a pixel circuit are formed over the same substrate can be obtained. In addition, there is an advantage that capital investment can be reduced because part of production equipment for a transistor including amorphous silicon can be retrofitted and utilized.

It is known that a transistor including an oxide semiconductor has an extremely low leakage current in an off state. For example, a CPU or the like with low-power consumption utilizing a characteristic of low leakage current of the transistor including an oxide semiconductor is disclosed (see Patent Document 2). Patent Document 3 discloses that a transistor having high field-effect mobility can be obtained by a well potential formed using an active layer formed of an oxide semiconductor.

### PATENT DOCUMENT

[Patent Document 1] Japanese Published Patent Application No. 2006-165528

[Patent Document 2] Japanese Published Patent Application No. 2012-257187

[Patent Document 3] Japanese Published Patent Application No. 2012-59860

### SUMMARY OF THE INVENTION

An object is to provide a transistor with a small subthreshold swing value. Another object is to provide a transistor with a low density of shallow interface states at an interface between a semiconductor and a gate insulator. Another object is to provide a transistor with favorable electrical characteristics. Another object is to provide a transistor having stable electrical characteristics. Another object is to provide a transistor with high frequency characteristics. Another object is to provide a transistor having low off-state current. Another object is to provide a semiconductor device including the transistor. Another object is to provide a module including the semiconductor device. Another object is to provide an electronic device including the semiconductor device or the module. Another object is to provide a novel semiconductor device. Another object is to provide a novel module. Another object is to provide a novel electronic device.

Another object is to provide a method for estimating the density of interface states at an interface between a semiconductor and a gate insulator of a transistor.

Note that the descriptions of these objects do not disturb the existence of other objects. In one embodiment of the present invention, there is no need to achieve all the objects. Other objects will be apparent from and can be derived from the description of the specification, the drawings, the claims, and the like.

(1) One embodiment of the present invention is a semiconductor device including an insulator, a semiconductor, and a conductor. The semiconductor includes a region in which the semiconductor and the conductor overlap each other with the insulator positioned therebetween, and the density of shallow interface states at an interface between the semiconductor and the insulator in the region is lower than or equal to 1×10¹³ cm⁻².

(2) Another embodiment of the present invention is the semiconductor device according to (1), in which the density of interface states is measured by a high-frequency C-V method.

(3) Another embodiment of the present invention is the semiconductor device according to (2), in which the high-frequency C-V method is performed in such a manner that an alternating voltage at 0.1 kHz or higher and 10 MHz or lower and a direct-current voltage are applied to the conductor.

(4) Another embodiment of the present invention is the semiconductor device according to any one of (1) to (3), in which the thickness of the semiconductor is greater than or equal to 1 nm and less than or equal to 200 nm.

(5) Another embodiment of the present invention is the semiconductor device according to any one of (1) to (4), in which the semiconductor includes an oxide containing at least one selected from indium, zinc and an element M (the element M is aluminum, gallium, yttrium, or tin).

A transistor with a small subthreshold swing value can be provided. A transistor with a low density of shallow interface states at an interface between a semiconductor and a gate insulator can be provided. A transistor with favorable electrical characteristics can be provided. A transistor having stable electrical characteristics can be provided. A transistor with high frequency characteristics can be provided. A transistor with low off-state current can be provided. A semiconductor device including the transistor can be provided. A module the semiconductor device can be provided. An electronic device including the above semiconductor device or the module can be provided. An novel semiconductor device can be provided. A novel module can be provided. A novel electronic device can be provided.

A method for estimating the density of interface states at an interface between a semiconductor and a gate insulator of a transistor can be provided.

Note that the description of these effects does not disturb the existence of other effects. One embodiment of the present invention does not necessarily achieve all the above effects. Other effects will be apparent from and can be derived from the description of the specification, the drawings, the claims, and the like.

### BRIEF DESCRIPTION OF THE DRAWINGS

FIG. 1 is a cross-sectional view of a transistor.

FIG. 2 shows C-V characteristics.

FIG. 3 shows C-V characteristics.

FIGS. 4A to 4C show band structures and C-V characteristics.

FIG. 5 shows C-V characteristics.

FIG. 6 shows the density of interface states.

FIGS. 7A and 7B show C-V characteristics and Id-Vg characteristics, respectively.

FIGS. 8A to 8C are a top view and cross-sectional views illustrating a transistor of one embodiment of the present invention.

FIGS. 9A and 9B are a top view and a cross-sectional view illustrating a transistor of one embodiment of the present invention.

FIGS. 10A and 10B are circuit diagrams of semiconductor devices of one embodiment of the present invention.

FIGS. 11A and 11B are circuit diagrams of memory devices of one embodiment of the present invention.

FIG. 12 is a block diagram illustrating a CPU of one embodiment of the present invention.

FIG. 13 is a circuit diagram of a memory element of one embodiment of the present invention.

FIGS. 14A to 14C are a top view and circuit diagrams of a display device of one embodiment of the present invention.

FIGS. 15A to 15F each illustrate an electronic device according to one embodiment of the present invention.

### DETAILED DESCRIPTION OF THE INVENTION

Embodiments of the present invention will be described in detail with reference to the drawings. However, the present invention is not limited to the description below, and it is easily understood by those skilled in the art that modes and details disclosed herein can be modified in various ways. Furthermore, the present invention is not construed as being limited to description of the embodiments. In describing structures of the present invention with reference to the drawings, common reference numerals are used for the same portions in different drawings. Note that the same hatched pattern is applied to similar parts, and the similar parts are not especially denoted by reference numerals in some cases.

Note that the size, the thickness of films (layers), or regions in drawings is sometimes exaggerated for clarity.

In this specification, the terms “film” and “layer” can be interchanged with each other.

A voltage usually refers to a potential difference between a given potential and a reference potential (e.g., a source potential or a ground potential (GND)). A voltage can be referred to as a potential and vice versa.

Note that the ordinal numbers such as “first” and “second” in this specification are used for convenience and do not denote the order of steps or the stacking order of layers. Therefore, for example, the term “first” can be replaced with the term “second”, “third”, or the like as appropriate. In addition, the ordinal numbers in this specification and the like do not correspond to the ordinal numbers which specify one embodiment of the present invention in some cases.

Note that a “semiconductor” includes characteristics of an “insulator” in some cases when the conductivity is sufficiently low, for example. Furthermore, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Furthermore, a “semiconductor” includes characteristics of a “conductor” in some cases when the conductivity is sufficiently high, for example. Furthermore, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of a semiconductor. For example, an element with a concentration lower than 0.1 atomic % is an impurity. When an impurity is contained, the density of states (DOS) may be formed in a semiconductor, the carrier mobility may be decreased, or the crystallinity may be decreased, for example. In the case where the semiconductor is an oxide semiconductor, examples of an impurity which changes characteristics of the semiconductor include Group 1 elements, Group 2 elements, Group 14 elements, Group 15 elements, and transition metals other than the main components; specifically, there are hydrogen (included in water), lithium, sodium, silicon, boron, phosphorus, carbon, and nitrogen, for example. When the semiconductor is an oxide semiconductor, oxygen vacancies may be formed by entry of impurities such as hydrogen, for example. Furthermore, when the semiconductor is silicon, examples of an impurity which changes the characteristics of the semiconductor include oxygen, Group 1 elements except hydrogen, Group 2 elements, Group 13 elements, and Group 15 elements.

In this specification, the phrase “A has a region with a concentration B” includes, for example, the cases where “the concentration in the entire region in a region of A in the depth direction is B”, “the average concentration in a region of A in the depth direction is B”, “the median value of the concentration in a region of A in the depth direction is B”, “the maximum value of the concentration in a region of A in the depth direction is B”, “the minimum value of the concentration in a region of A in the depth direction is B”, “a convergence value of the concentration in a region of A in the depth direction is B”, and “a concentration in a region of A in which a probable value is obtained in measurement is B”.

In this specification, the phrase “A has a region with a size B, a length B, a thickness B, a width B, or a distance B” includes, for example, “the size, the length, the thickness, the width, or the distance of the entire region in a region of A is B”, “the average value of the size, the length, the thickness, the width, or the distance of a region of A is B”, “the median value of the size, the length, the thickness, the width, or the distance of a region of A is B”, “the maximum value of the size, the length, the thickness, the width, or the distance of a region of A is B”, “the minimum value of the size, the length, the thickness, the width, or the distance of a region of A is B”, “a convergence value of the size, the length, the thickness, the width, or the distance of a region of A is B”, and “the size, the length, the thickness, the width, or the distance of a region of A in which a probable value is obtained in measurement is B”.

Note that the channel length refers to, for example, a distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where a current flows in a semiconductor when a transistor is on) and a gate electrode overlap with each other or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on a transistor structure, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of the semiconductor in some cases. In that case, an effective channel width obtained when a channel is actually formed is greater than an apparent channel width shown in the top view.

In a transistor having a three-dimensional structure, an effective channel width is difficult to measure in some cases. For example, estimation of an effective channel width from a design value requires an assumption that the shape of a semiconductor is known. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Furthermore, in this specification, in the case where the term “channel width” is simply used, it may denote a surrounded channel width or an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where field-effect mobility, a current value per channel width, and the like of a transistor are obtained by calculation, a surrounded channel width may be used for the calculation. In that case, a value different from one in the case where an effective channel width is used for the calculation is obtained in some cases.

Note that in this specification, the description “A has a shape such that an end portion extends beyond an end portion of B” may indicate, for example, the case where at least one of end portions of A is positioned on an outer side than at least one of end portions of B in a top view or a cross-sectional view. Thus, the description “A has a shape such that an end portion extends beyond an end portion of B” can be alternatively referred to as the description “one of end portions of A is positioned on an outer side than one of end portions of B”.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly includes the case where the angle is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

### <Transistor>

A transistor of one embodiment of the present invention is described below.

### <Transistor Structure 1>

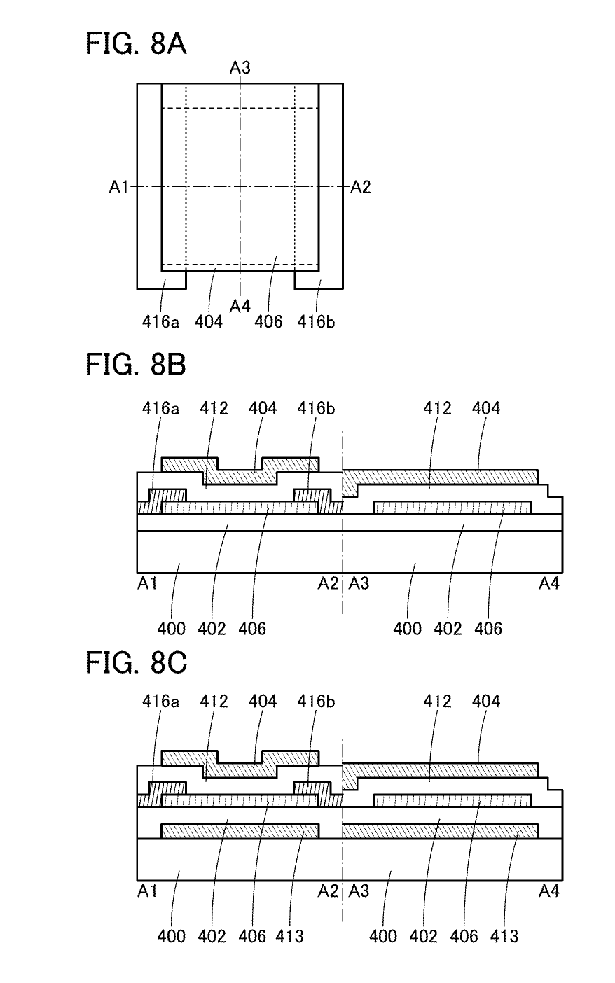

FIGS. 8A and 8B are a top view and a cross-sectional view of a transistor of one embodiment of the present invention. FIG. 8A is a top view and FIG. 8B is a cross-sectional view taken along dashed-dotted line A1-A2 and dashed-dotted line A3-A4 in FIG. 8A. Note that for simplification of the drawing, some components in the top view in FIG. 8A are not illustrated.

The transistor illustrated in FIGS. 8A and 8B includes an insulator 402 over a substrate 400, a semiconductor 406 over the insulator 402, conductors 416a and 416b over the semiconductor 406, an insulator 412 over the semiconductor 406 and the conductors 416a and 416b, and a conductor 404 including a region that overlaps the semiconductor 406 with the insulator 412 positioned therebetween.

Note that the semiconductor 406 functions as a channel formation region of the transistor. The insulator 412 functions as a gate insulator of the transistor. The conductor 404 functions as a gate electrode of the transistor. The conductors 416a and 416b function as source and drain electrodes of the transistor.

In the transistor in FIGS. 8A and 8B, the density of shallow interface states at the interface between the semiconductor 406 and the insulator 412 in a region where the semiconductor 406 and the conductor 404 overlap each other with the insulator 412 positioned therebetween is lower than or equal to 1×10¹³ cm⁻², preferably lower than or equal to 6×10¹² cm⁻², further preferably lower than or equal to 3×10¹² cm⁻², still further preferably lower than or equal to 1×10¹² cm⁻². When the density of shallow interface states is lower than any of the above values, the subthreshold swing value (also referred to as the S-value) of the transistor can be small. Therefore, the on and off states of the transistor can be switched by a small change in the gate voltage. Thus, the power consumption of the transistor becomes small. Furthermore, in the transistor with normally-off electrical characteristics, a drain current at a gate voltage of 0 V (also referred to as leakage current) can be small. Furthermore, a change in electrical characteristics of the transistor can be reduced.

### <C-V Measurement>

A method for estimating the density of interface states of a transistor is described below.

The density of interface states can be estimated by comparison of actually measured high-frequency C-V characteristics of a transistor with calculated C-V characteristics thereof, for example.

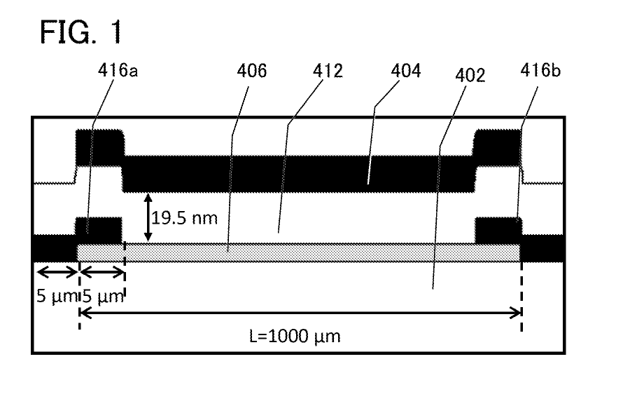

FIG. 1 is a cross-sectional view of the transistor used for calculation. The transistor used for actual measurement also has a similar cross-sectional structure. A device simulator “Atlas” developed by Silvaco Inc. was used for the calculation. The following table lists parameters used for the calculation. Note that Eg represents an energy gap, Nc represents the effective density of states in the conduction band, and Nv represents the effective density of states in the valence band.

TABLE 1

| | | | |
|---|---|---|---|
| Structure | Channel width | 1000 | μm |
| | Channel length | 1000 | μm |
| Conductor 404 | Work function | 5 | eV |
| Insulator 412 | Thickness | 19.5 | nm |
| | Dielectric constant | 4.1 | |
| Conductor 416a | Work function | 4.6 | eV |
| Conductor 416b | | | |
| Semiconductor 406 | Electron affinity | 4.6 | eV |
| | Eg | 3.15 | eV |
| | Dielectric constant | 15 | |
| | Donor density | 6.6 × 10⁻⁹ | cm⁻³ |
| | Electron mobility | 10 | cm²/Vsec |
| | Hole mobility | 0 | cm²/Vsec |
| | Nc | 5 × 10¹⁸ | cm⁻³ |
| | Nv | 5 × 10¹⁸ | cm⁻³ |
| | Thickness | 30 | nm |

Although not shown in the table, the donor density of the semiconductor 406 in a region where the semiconductor 406 and the conductors 416a and 416b are in contact with each other is set to 1×10¹⁹ cm⁻³.

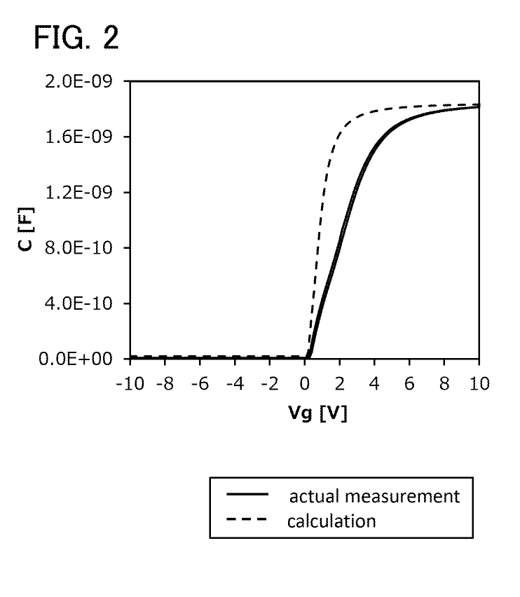

The C-V characteristics obtained by calculation (dashed line) and the C-V characteristics obtained by actual measurement (solid line) are both shown in FIG. 2. In—Ga—Zn oxide was used as the semiconductor 406 in the transistor that was subjected to actual measurement. The measurement of the C-V characteristics was performed in such a manner that a voltage between the conductors 416a and 416b and the conductor 404 (also referred to as a gate voltage Vg) was swept from −10 V to 10 V in increments of 0.1 V, and then swept from 10 V to −10 V in increments of 0.1 V. An alternating voltage at 1 kHz and a direct-current voltage were applied as the gate voltage Vg.

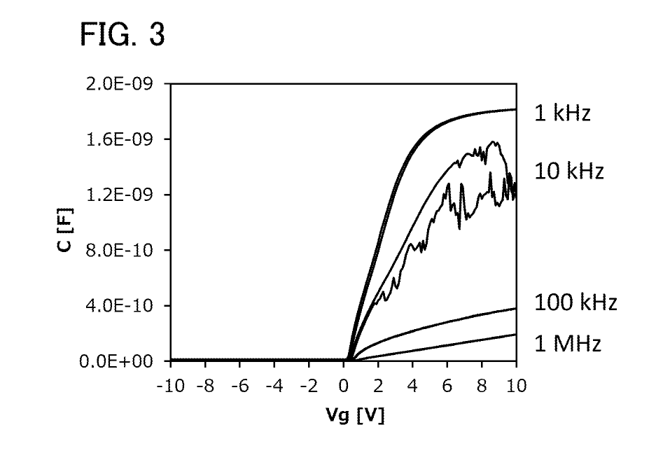

FIG. 3 shows C-V characteristics obtained by actual measurement of the transistor with the use of alternating voltages at 1 kHz, 10 kHz, 100 kHz, and 1 MHz. Note that large noise with an alternating voltage at 10 kHz is not due to frequency.

As shown in FIG. 3, an increase in the frequency of the alternating voltage reduces measured capacitance. In the condition where the measured capacitance is small, there is a possibility that the result does not sufficiently reflect a change in the capacitance in the measured region. Thus, the C-V characteristics with the alternating voltage at 1 kHz is used as an actually measured value in FIG. 2. Note that the insufficient reflection of the change in the capacitance in the measured region is caused owing to a large channel length of the transistor. Therefore, in the case where the channel length of the transistor is smaller than 1000 μm, in some cases, the result fully reflects the change in the capacitance in the measured region even with an alternating voltage at a frequency higher than 1 kHz. That is, the frequency of the alternating voltage may be selected as appropriate in accordance with the channel length of the transistor. Note that the frequency of the alternating voltage in the case of a practical channel length of a transistor is, for example, higher than or equal to 0.1 kHz and lower than or equal to 10 MHz, higher than or equal to 0.2 kHz and lower than or equal to 1 MHz, higher than or equal to 0.3 kHz and lower than or equal to 100 kHz, or higher than or equal to 0.3 kHz and lower than or equal to 10 kHz.

As shown in FIG. 2, a change in the capacitance (represented as C) with respect to the gate voltage Vg is more gradual in the actually measured C-V characteristics than in ideal C-V characteristics obtained by calculation. This is probably because an electron is trapped by a shallow interface state positioned near the conduction band minimum (represented as Ec).

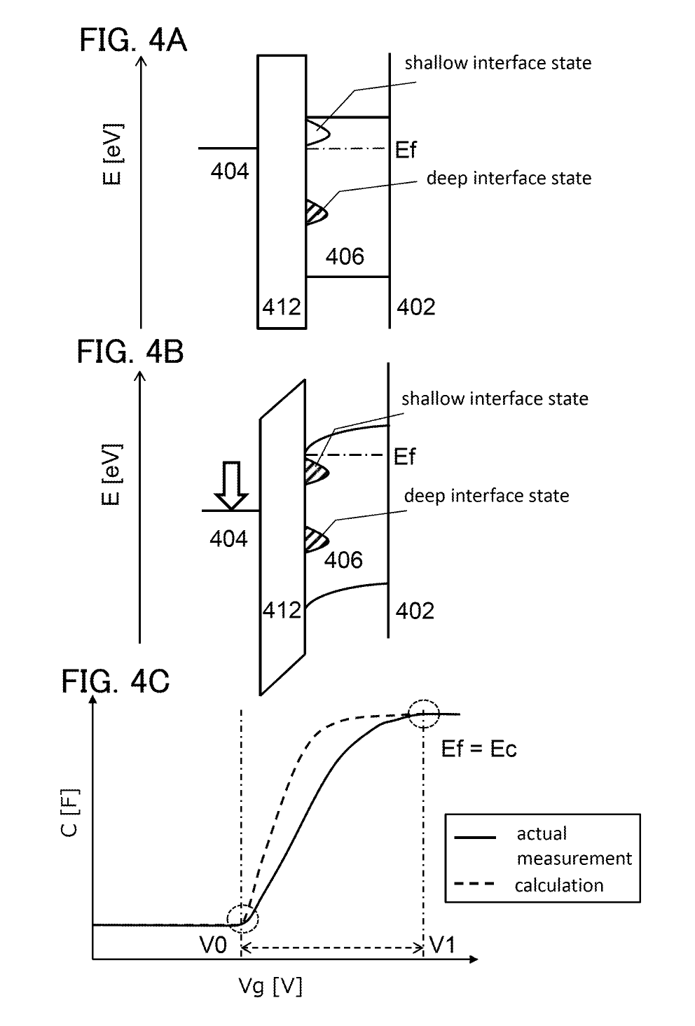

For example, in a band structure shown in FIG. 4A, an electron is not trapped by a shallow interface state in the energy gap of the semiconductor 406 but trapped by a deep interface state, at a gate voltage Vg when accumulation begins (represented as V0). Meanwhile, in a band structure shown in FIG. 4B where a positive voltage is applied as the gate voltage Vg, the band of the semiconductor 406 is curved, whereby an electron is also trapped by the shallow interface state. These phenomena can be understood by the relationship between the shallow or deep interface state and the Fermi level Ef.

Note that when the gate voltage Vg is lower than V0, trapping and detrapping of an electron in and from the shallow interface state do not occur; thus, there is no difference between the calculated value and the actually measured value. Furthermore, when the gate voltage Vg is set higher than the gate voltage Vg (represented as V1) at which the conduction band minimum corresponds to the Fermi level, trapping and detrapping of an electron in and from the shallow interface state do not also occur at the interface between the semiconductor 406 and the insulator 412; accordingly, there is no difference between the calculated value and the actually measured value. Therefore, when the gate voltage Vg is within a range from V0 to V1, the shallow interface state can be estimated.

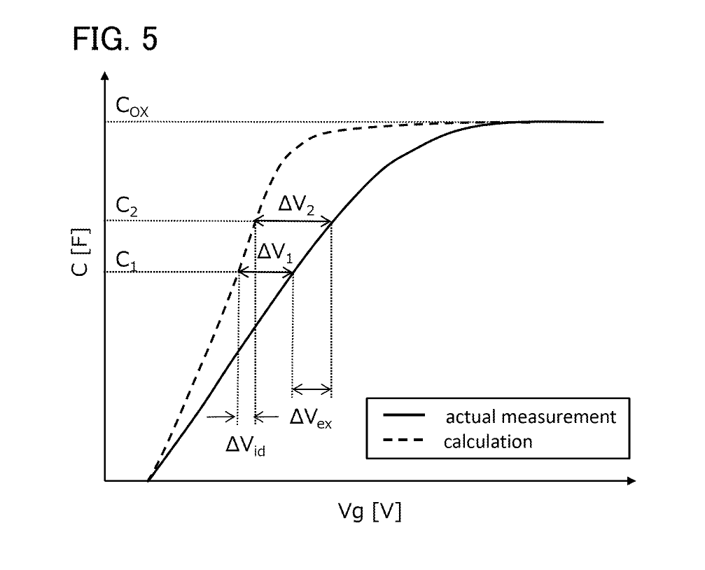

A method for estimating a shallow interface state using, for example, typical C-V characteristics shown in FIG. 5 is described. A change in the gate voltage Vg when the capacitance changes from C1 to C2 in ideal C-V characteristics obtained by calculation is represented as ΔV_{id}. A change in the gate voltage Vg when the capacitance changes from C1 to C2 in actually measured C-V characteristics is represented as ΔVₑₓ. The amount of change in potential at the interface between the semiconductor 406 and the insulator 412 when the capacitance changes from C1 to C2 is represented as Δφ.

The slope of the actually measured value is more gradual than that of the calculated value in FIG. 5, which indicates that ΔV_{id} is always smaller than ΔVₑₓ. At this time, a difference between ΔVₑₓ and ΔV_{id} corresponds to a potential difference that is needed for trapping of an electron in a shallow interface state. Thus, when the amount of change in charge due to electrons trapped at the interface between the semiconductor 406 and the insulator 412 is represented as ΔQₛₛ and the capacitance of the insulator 412 is represented as C_{OX}, ΔQₛₛ can be expressed by Formula (1) shown below.

[Formula 1]

ΔQ_{SS}=C_{OX}(ΔVₑₓ−ΔV_{id} (1)

Furthermore, ΔQₛₛ can also be expressed by Formula (2), where Nₛₛ is the density of shallow interface states per unit area multiplied by energy at the interface between the semiconductor 406 and the insulator 412 and A is the area of the channel region of the transistor. Note that q represents elementary charge.

[Formula 2]

ΔQ_{SS}=qAN_{SS}Δφ (2)

Simultaneously solving the formulae (1) and (2) gives Formula (3).

[Formula 3]

qAN_{SS}Δφ=C_{OX}(ΔVₑₓ−ΔV_{id}) (3)

Then, taking the limit of Formula (3) gives Formula (4).

$$\begin{matrix}[ Formula 4 ] & \\ {N}_{SS} = {lim}_{Δφ \to 0} \frac{{C}_{OX}}{qA} ( \frac{Δ {V}_{ex} - Δ {V}_{id}}{Δφ} ) = \frac{{C}_{OX}}{qA} ( \frac{\partial {V}_{ex}}{\partial φ} - \frac{\partial {V}_{id}}{\partial φ} ) & ( 4 )\end{matrix}$$

In other words, the density of shallow interface states (Nₛₛ) at the interface between the semiconductor 406 and the insulator 412 can be derived from the C-V characteristics and Formula (4). Note that the potential at the interface between the semiconductor 406 and the insulator 412 can be derived by the above calculation.

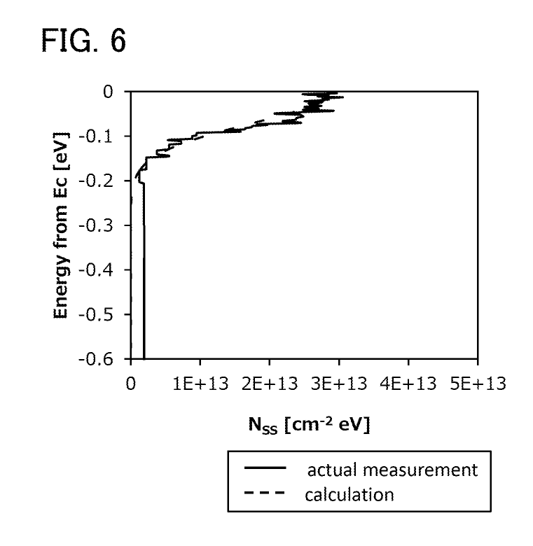

In the above manner, the density of shallow interface states (Nₛₛ) at the interface between the semiconductor 406 and the insulator 412 in the C-V characteristics shown in FIG. 2 can be derived (see FIG. 6). As shown in FIG. 6, the shallow interface states in the semiconductor 406 are positioned in a range of an energy value of the conduction band minimum (Ec) to 0.2 eV in the semiconductor. The distribution of the density of shallow interface states corresponds to a curve represented by Formula (5) that has been fitted to the Gaussian function. Note that N is 2.9×10¹³ cm⁻² eV, and W is 0.10 eV.

$$\begin{matrix}[ Formula 5 ] & \\ {N}_{SS} = N exp [ - \frac{{( {E}_{C} - E )}^{2}}{{W}^{2}} ] & ( 5 )\end{matrix}$$

From the integral of the curve, 2.6×10¹² cm⁻² is given as the density of shallow interface states.

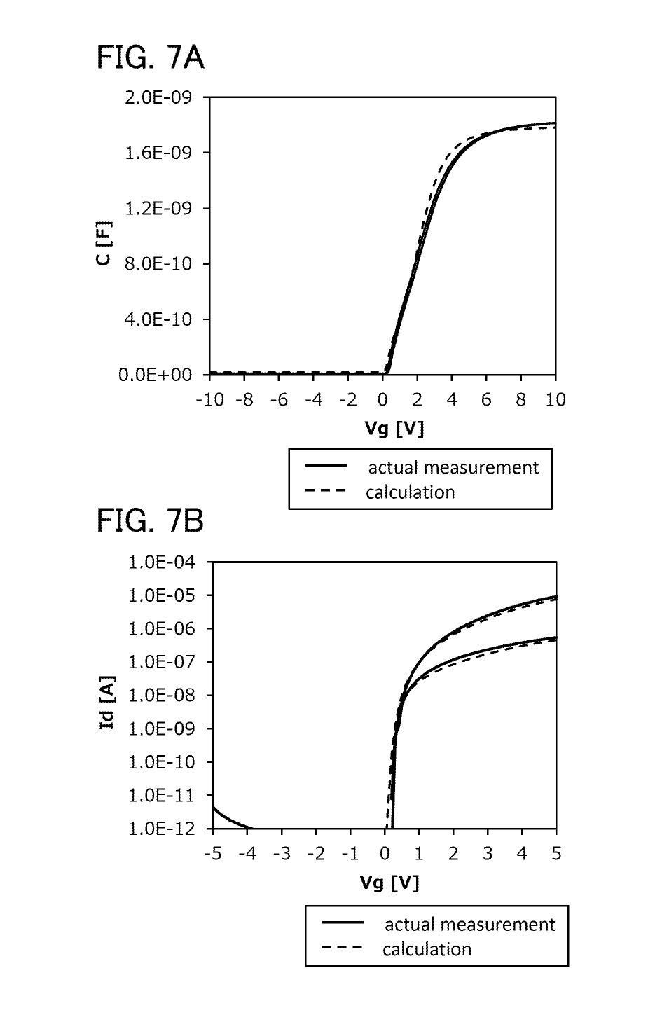

Next, C-V characteristics are calculated using the Gaussian-type density of shallow interface states represented by Formula (5). Comparison between the C-V characteristics obtained by actual measurement and the C-V characteristics obtained by calculation is shown in FIG. 7A. The results indicate that the calculated C-V characteristics and the actually measured C-V characteristics are highly reproducible. Next, FIG. 7B shows Id-Vg characteristics of the transistors, which shows that the calculated Id-Vg characteristics and the actually measured Id-Vg characteristics are highly reproducible.

Accordingly, the above method is quite appropriate as a method for estimating the density of shallow interface states.

To obtain a transistor with favorable electrical characteristics, for example, the density of shallow interface states at the interface between the semiconductor 406 and the insulator 412 is set lower than or equal to 1×10¹³ cm⁻², preferably lower than or equal to 6×10¹² cm⁻², further preferably lower than or equal to 3×10¹² cm⁻², still further preferably lower than or equal to 1×10¹² cm⁻².

### <Components of Transistor Structure 1>

Examples of components of the transistor are described below.

As the substrate 400, an insulator substrate, a semiconductor substrate, or a conductor substrate may be used, for example. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a single material semiconductor substrate of silicon, germanium, or the like or a compound semiconductor substrate of silicon carbide, silicon germanium, gallium arsenide, indium phosphide, zinc oxide, gallium oxide, or the like is used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate 400. As a method for providing a transistor over a flexible substrate, there is a method in which the transistor is formed over a non-flexible substrate and then the transistor is separated and transferred to the substrate 400 which is a flexible substrate. In that case, a separation layer is preferably provided between the non-flexible substrate and the transistor. As the substrate 400, a sheet, a film, or a foil containing a fiber may be used. The substrate 400 may have elasticity. The substrate 400 may have a property of returning to its original shape when bending or pulling is stopped. Alternatively, the substrate 400 may have a property of not returning to its original shape. The thickness of the substrate 400 is, for example, greater than or equal to 5 μm and less than or equal to 700 μm, preferably greater than or equal to 10 μm and less than or equal to 500 μm, more preferably greater than or equal to 15 μm and less than or equal to 300 μm. When the substrate 400 has a small thickness, the weight of the semiconductor device can be reduced. When the substrate 400 has a small thickness, even in the case of using glass or the like, the substrate 400 may have elasticity or a property of returning to its original shape when bending or pulling is stopped. Therefore, an impact applied to the semiconductor device over the substrate 400, which is caused by dropping or the like, can be reduced. That is, a durable semiconductor device can be provided.

For the substrate 400 which is a flexible substrate, metal, an alloy, resin, glass, or fiber thereof can be used, for example. The flexible substrate 400 preferably has a lower coefficient of linear expansion because deformation due to an environment is suppressed. The flexible substrate 400 is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, acrylic, and polytetrafluoroethylene (PTFE). In particular, aramid is preferably used for the flexible substrate 400 because of its low coefficient of linear expansion.

The insulator 402 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 402 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 402 may have a function of preventing diffusion of impurities from the substrate 400. In the case where the semiconductor 406 is an oxide semiconductor, the insulator 402 can have a function of supplying oxygen to the semiconductor 406.

The insulator 402 is preferably an insulator containing excess oxygen.

The insulator containing excess oxygen means an insulator from which oxygen is released by heat treatment, for example. The silicon oxide layer containing excess oxygen means a silicon oxide layer which can release oxygen by heat treatment or the like, for example. Therefore, the insulator 402 is an insulator in which oxygen can be moved. In other words, the insulator 402 may be an insulator having an oxygen-transmitting property. For example, the insulator 402 may be an insulator having a higher oxygen-transmitting property than the semiconductor 406.

The insulator containing excess oxygen has a function of reducing oxygen vacancies in the semiconductor 406 in some cases. Such oxygen vacancies form deep states in the semiconductor 406 and serve as hole traps or the like. In addition, hydrogen comes into the site of such oxygen vacancies and forms electrons serving as carriers. Therefore, by reducing the oxygen vacancies in the semiconductor 406, the transistor can have stable electrical characteristics.

Here, an insulator from which oxygen is released by heat treatment may release oxygen, the amount of which is higher than or equal to 1×10¹⁸ atoms/cm³, higher than or equal to 1×10¹⁹ atoms/cm³, or higher than or equal to 1×10²⁰ atoms/cm³ (converted into the number of oxygen atoms) in TDS analysis in the range of a surface temperature of 100° C. to 700° C. or 100° C. to 500° C.

Here, the method for measuring the amount of released oxygen using TDS analysis is described below.

The total amount of released gas from a measurement sample in TDS analysis is proportional to the integral value of the ion intensity of the released gas. Then, comparison with a reference sample is made, whereby the total amount of released gas can be calculated.

For example, the number of released oxygen molecules (N_{O2}) from a measurement sample can be calculated according to the following formula using the TDS results of a silicon substrate containing hydrogen at a predetermined density, which is a reference sample, and the TDS results of the measurement sample. Here, all gases having a mass-to-charge ratio of 32 which are obtained in the TDS analysis are assumed to originate from an oxygen molecule. Note that CH₃OH, which is a gas having the mass-to-charge ratio of 32, is not taken into consideration because it is unlikely to be present. Furthermore, an oxygen molecule including an oxygen atom having a mass number of 17 or 18 which is an isotope of an oxygen atom is also not taken into consideration because the proportion of such a molecule in the natural world is minimal.

N_{O2}=N_{H2}/S_{H2}×S_{O2}×α

The value N_{H2} is obtained by conversion of the number of hydrogen molecules desorbed from the reference sample into densities. The value S_{H2} is the integral value of ion intensity in the case where the reference sample is subjected to the TDS analysis. Here, the reference value of the reference sample is set to N_{H2}/S_{H2}. The value S_{O2} is the integral value of ion intensity when the measurement sample is analyzed by TDS. The value α is a coefficient affecting the ion intensity in the TDS analysis. Refer to Japanese Published Patent Application No. H6-275697 for details of the above formula. The amount of released oxygen is measured with a thermal desorption spectroscopy apparatus produced by ESCO Ltd., EMD-WA1000S/W using a silicon substrate containing hydrogen atoms at 1×10¹⁶ atoms/cm², for example, as the reference sample.

Furthermore, in the TDS analysis, oxygen is partly detected as an oxygen atom. The ratio between oxygen molecules and oxygen atoms can be calculated from the ionization rate of the oxygen molecules. Note that since the above a includes the ionization rate of the oxygen molecules, the amount of the released oxygen atoms can also be estimated through the evaluation of the amount of the released oxygen molecules.

Note that N_{O2} is the amount of the released oxygen molecules. The amount of released oxygen in the case of being converted into oxygen atoms is twice the amount of the released oxygen molecules.

Furthermore, the insulator from which oxygen is released by heat treatment may contain a peroxide radical. Specifically, the spin density attributed to the peroxide radical is greater than or equal to 5×10¹⁷ spins/cm³. Note that the insulator containing a peroxide radical may have an asymmetric signal with a g factor of approximately 2.01 in ESR.

The insulator containing excess oxygen may be formed using oxygen-excess silicon oxide (SiO_{X} (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

An oxide semiconductor is preferably used as the semiconductor 406. Note that silicon (including strained silicon), germanium, silicon germanium, silicon carbide, gallium arsenide, aluminum gallium arsenide, indium phosphide, gallium nitride, an organic semiconductor, or the like can be used in some cases.

The case where the semiconductor 406 is a stacked-layer film in which a first semiconductor layer, a second semiconductor layer, and a third semiconductor layer are stacked in this order is described below.

Semiconductors which can be used for the first to third semiconductor layers are described.

The second semiconductor layer is an oxide semiconductor containing indium, for example. The second semiconductor layer can have high carrier mobility (electron mobility) by containing indium, for example. The second semiconductor layer preferably contains an element M. The element M is preferably aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like. Note that two or more of the above elements may be used in combination as the element M. The element M is an element having a high bonding energy with oxygen, for example. The element M is an element whose bonding energy with oxygen is higher than that of indium. The element M is an element that can increase the energy gap of the oxide semiconductor, for example. Furthermore, the second semiconductor layer preferably contains zinc. When the oxide semiconductor contains zinc, the oxide semiconductor is easily to be crystallized, for example.

Note that the second semiconductor layer is not limited to the oxide semiconductor containing indium. The second semiconductor layer may be, for example, an oxide semiconductor which does not contain indium and contains zinc, an oxide semiconductor which does not contain indium and contains gallium, or an oxide semiconductor which does not contain indium and contains tin, e.g., zinc tin oxide, gallium tin oxide, or gallium oxide.

For the second semiconductor layer, an oxide with a wide energy gap is used. The energy gap of the second semiconductor layer is, for example, 2.5 eV or larger and 4.2 eV or smaller, preferably 2.8 eV or larger and 3.8 eV or smaller, more preferably 3 eV or larger and 3.5 eV or smaller.

For example, the first and third semiconductor layers are each an oxide semiconductor which includes one or more, or two or more elements other than oxygen that are included in the second semiconductor layer. Because the first and third semiconductor layers each include one or more, or two or more elements other than oxygen that are included in the second semiconductor layer, an interface state is less likely to be formed at the interface between the first semiconductor layer and the second semiconductor layer and the interface between the second semiconductor layer and the third semiconductor layer.

The case where the first to third semiconductor layers each include indium is described below. In the case where an In-M-Zn oxide is used for the first semiconductor layer, when the summation of In and M is assumed to be 100 atomic %, the proportions of In and M are preferably set to be less than 50 atomic % and greater than 50 atomic %, respectively, further preferably less than 25 atomic % and greater than 75 atomic %, respectively. In the case an In-M-Zn oxide is used for the second semiconductor layer, when the summation of In and M is assumed to be 100 atomic %, the proportions of In and M are preferably set to be greater than 25 atomic % and less than 75 atomic %, respectively, more preferably greater than 34 atomic % and less than 66 atomic %, respectively. In the case where an In-M-Zn oxide is used for the third semiconductor layer, when the summation of In and M is assumed to be 100 atomic %, the proportions of In and M are preferably set to be less than 50 atomic % and greater than 50 atomic %, respectively, more preferably less than 25 atomic % and greater than 75 atomic %, respectively. Note that the third semiconductor layer may be formed using the same kind of oxide as that of the first semiconductor layer.

For the second semiconductor layer, an oxide having an electron affinity higher than those of the first and third semiconductor layers is used. For example, as the second semiconductor layer, an oxide having higher electron affinity than those of the first and third semiconductor layers by greater than or equal to 0.07 eV and less than or equal to 1.3 eV, preferably greater than or equal to 0.1 eV and less than or equal to 0.7 eV, further preferably greater than or equal to 0.15 eV and less than or equal to 0.4 eV is used. Note that the electron affinity refers to an energy gap between the vacuum level and the conduction band minimum.

Indium gallium oxide has a small electron affinity and a high oxygen-blocking property. Therefore, the third semiconductor layer preferably includes indium gallium oxide. The gallium atomic ratio [Ga/(In+Ga)] is, for example, higher than or equal to 70%, preferably higher than or equal to 80%, more preferably higher than or equal to 90%.

Note that the first semiconductor layer and/or the third semiconductor layer may be gallium oxide. For example, when gallium oxide is used for the third semiconductor layer, a leakage current generated between the conductor 404 and the conductor 416a or 416b can be reduced. In other words, the off-state current of the transistor can be reduced.

At this time, when a gate voltage is applied, a channel is formed in the second semiconductor layer, which has the largest electron affinity among the first to third semiconductor layers. The channel may be formed in two or three layers selected from the first to third semiconductor layers.

Here, a mixed region of the first and second semiconductor layers might be provided between the first and second semiconductor layers. In addition, a mixed region of the second and third semiconductor layers might be provided between the second and third semiconductor layers. The mixed region has a low density of shallow interface states. For that reason, the stack including the first to third semiconductor layers has a band structure in which energy at each interface and in the vicinity of the interface is changed continuously (continuous junction).

At this time, electrons move mainly in the second semiconductor layer, not in the first and third semiconductor layers. Thus, reduction in the density of shallow interface states at the interface between the first and second semiconductor layers and the density of shallow interface states at the interface between the second and third semiconductor layers prevent inhibition of electron movement in the second semiconductor layer and can increase the on-sate current of the transistor.

Note that the thickness of the third semiconductor layer is preferably as small as possible to increase the on-state current of the transistor. The third semiconductor layer preferably has a region with a thickness of less than 10 nm, preferably less than or equal to 5 nm, more preferably less than or equal to 3 nm, for example. Meanwhile, the third semiconductor layer has a function of blocking the entry of elements other than oxygen (such as hydrogen and silicon) included in the adjacent insulator into the second semiconductor where the channel is formed. For this reason, it is preferable that the third semiconductor layer have a certain thickness. For example, the third semiconductor layer may include a region with a thickness of greater than or equal to 0.3 nm, preferably greater than or equal to 1 nm, and further preferably greater than or equal to 2 nm. Moreover, the third semiconductor layer preferably has an oxygen blocking property to inhibit outward diffusion of oxygen released from the insulator 402 and the like.

To improve reliability, it is preferable that the thickness of the first semiconductor layer be large and the thickness of the third semiconductor layer be small. For example, the first semiconductor layer may include a region with a thickness of greater than or equal to 10 nm, preferably greater than or equal to 20 nm, further preferably greater than or equal to 40 nm, and still further preferably greater than or equal to 60 nm. When the thickness of the first semiconductor layer is made large, a distance from an interface between the adjacent insulator and the first semiconductor layer to the second semiconductor layer where the channel is formed can be large. Since the productivity of the semiconductor device including the transistor might be decreased, the first semiconductor layer has a region with a thickness, for example, less than or equal to 200 nm, preferably less than or equal to 120 nm, or further preferably less than or equal to 80 nm.

For example, silicon in the oxide semiconductor might serve as a carrier trap or a carrier generation source. Therefore, the silicon concentration of the second semiconductor layer is preferably as low as possible. For example, a region with a silicon concentration of lower than 1×10¹⁹ atoms/cm³, preferably lower than 5×10¹⁸ atoms/cm³, or further preferably lower than 2×10¹⁸ atoms/cm³ which is measured by secondary ion mass spectrometry (SIMS) is provided between the second and first semiconductor layers. A region with a silicon concentration of lower than 1×10¹⁹ atoms/cm³, preferably lower than 5×10¹⁸ atoms/cm³, more preferably lower than 2×10¹⁸ atoms/cm³ which is measured by SIMS is provided between the second and third semiconductor layers.

The second semiconductor layer has a region in which the hydrogen concentration which is measured by SIMS is lower than or equal to 2×10²⁰ atoms/cm³, preferably lower than or equal to 5×10¹⁹ atoms/cm³, further preferably lower than or equal to 1×10¹⁹ atoms/cm³, or still further preferably lower than or equal to 5×10¹⁸ atoms/cm³. To reduce the hydrogen concentration of the second semiconductor layer, the hydrogen concentrations of the first and third semiconductor layers are preferably reduced. The first and third semiconductor layers each have a region in which the hydrogen concentration measured by SIMS is lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³. The second semiconductor layer has a region in which the nitrogen concentration measured by SIMS is lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³. To reduce the nitrogen concentration of the second semiconductor layer, the nitrogen concentrations of the first and third semiconductor layers are preferably reduced. The first and third semiconductor layers each have a region in which the nitrogen concentration measured by SIMS is lower than or equal to 5×10¹⁹ atoms/cm³, preferably less than or equal to 5×10¹⁸ atoms/cm³, further preferably less than or equal to 1×10¹⁸ atoms/cm³, still more preferably less than or equal to 5×10¹⁷ atoms/cm³.

Note that when copper enters the oxide semiconductor, an electron trap might be generated. The electron trap might shift the threshold voltage of the transistor in the positive direction. Therefore, the copper concentration on the surface of or in the second semiconductor layer is preferably as low as possible. For example, the second semiconductor layer preferably has a region in which the copper concentration is lower than or equal to 1×10¹⁹ atoms/cm³, lower than or equal to 5×10¹⁸ atoms/cm³, or lower than or equal to 1×10¹⁸ atoms/cm³.

The above three-layer structure is an example. For example, a two-layer structure without the first or third semiconductor layer may be employed. A four-layer structure may be employed, in which any one of the semiconductors described as examples of the first to third semiconductor layers is provided below or over the first semiconductor layer or below or over the third semiconductor layer. Alternatively, an n-layer structure (n is an integer of 5 or more) may be employed, in which one or more of the semiconductors described as the examples of the first to third semiconductor layers are provided in two or more of the following positions: over the first semiconductor layer; below the first semiconductor layer; over the third semiconductor layer; and below the third semiconductor layer.

Each of the conductors 416a and 416b may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound of the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

The insulator 412 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 412 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The conductor 404 may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound of the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

### <Modification Example of Transistor Structure 1>

The transistor of one embodiment of the present invention may include a conductor 413 between the substrate 400 and the insulator 402 as illustrated in FIG. 8C. The conductor 413 functions as a second gate electrode (also referred to as a back gate electrode) of the transistor.

For example, a voltage which is the same as that applied to the conductor 404 can be applied to the conductor 413. Thus, an electric field can be applied from upper and lower sides of the semiconductor 406, resulting in increased on-state current of the transistor. In addition, the off-state current of the transistor can be reduced. Alternatively, for example, a voltage lower or higher than that applied to the source electrode may be applied to the conductor 413 so that the threshold voltage of the transistor may be shifted in the positive or negative direction. For example, by shifting the threshold voltage of the transistor in the positive direction, a normally-off transistor in which the transistor is in a non-conduction state (off state) even when the gate voltage is 0 V can be achieved in some cases. The voltage applied to the conductor 413 may be a variable or a fixed voltage. When the voltage applied to the conductor 413 is a variable, a circuit for controlling the voltage may be electrically connected to the conductor 413.

The density of shallow interface states at the interface between the insulator 402 and the semiconductor 406 can be estimated using the conductor 413 by the above-described estimation method.

The density of shallow interface states at the interface between the insulator 402 and the semiconductor 406 is lower than or equal to 1×10¹³ cm⁻², preferably lower than or equal to 6×10¹² cm⁻², further preferably lower than or equal to 3×10¹² cm⁻², still further preferably lower than or equal to 1×10¹² cm⁻². When the density of shallow interface states is lower than the above values, the S-value of the transistor can be small. Thus, the on and off states of the transistor can be switched by a small change in the gate voltage. Therefore, the power consumption of the transistor becomes small. Furthermore, in the transistor with normally-off electrical characteristics, a drain current at a gate voltage of 0 V (also referred to as leakage current) can be small. Moreover, a change in electrical characteristics of the transistor can be reduced.

The conductor 413 may be formed to have a single-layer structure or a stacked-layer structure using a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten, for example. An alloy or a compound of the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

### <Transistor Structure 2>

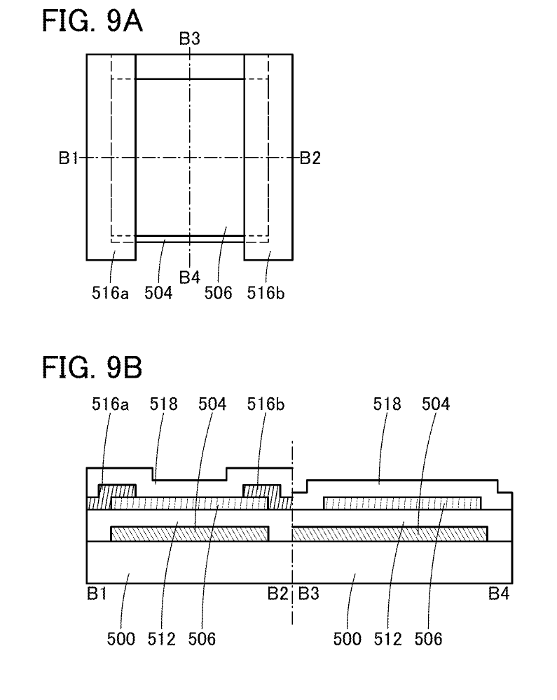

FIGS. 9A and 9B are a top view and a cross-sectional view of a transistor of one embodiment of the present invention. FIG. 9A is a top view and FIG. 9B is a cross-sectional view taken along dashed-dotted line B1-B2 and dashed-dotted line B3-B4 in FIG. 9A. Note that for simplification of the drawing, some components in the top view in FIG. 9A are not illustrated.

The transistor illustrated in FIGS. 9A and 9B includes a conductor 504 over a substrate 500, an insulator 512 over the conductor 504, a semiconductor 506 over the insulator 512, conductors 516a and 516b in contact with the top surface of the semiconductor 506 and arranged with a distance provided therebetween, and an insulator 518 over the semiconductor 506, the conductor 516a, and the conductor 516b. Note that the conductor 504 includes a region over which the semiconductor 506 is positioned with the insulator 512 provided therebetween. An insulator may be provided between the substrate 500 and the conductor 504. For the insulator, the description of the insulator 402 is referred to. The insulator 518 is not necessarily provided.

Note that the semiconductor 506 functions as a channel formation region of the transistor. The conductor 504 functions as a first gate electrode (also referred to as a front gate electrode) of the transistor. The insulator 512 functions as a gate insulator of the transistor. The conductor 516a and the conductor 516b function as a source electrode and a drain electrode of the transistor.

In the transistor illustrated in FIGS. 9A and 9B, the density of shallow interface states at the interface between the semiconductor 506 and the insulator 512 in a region where the semiconductor 506 and the conductor 504 overlap each other with the insulator 512 positioned therebetween is lower than or equal to 1×10¹³ cm⁻², preferably lower than or equal to 6×10¹² cm⁻², further preferably lower than or equal to 3×10¹² cm⁻², still further preferably lower than or equal to 1×10¹² cm⁻². When the density of shallow interface states is lower than the above values, the S-value of the transistor can be small. Thus, the on and off states of the transistor can be switched by a small change in the gate voltage. Therefore, the power consumption of the transistor becomes small. Furthermore, in the transistor with normally-off electrical characteristics, a drain current at a gate voltage of 0 V (also referred to as leakage current) can be small. Moreover, a change in electrical characteristics of the transistor can be reduced.

The insulator 518 is preferably an insulator containing excess oxygen.

For the substrate 500, the description of the substrate 400 is referred to. For the conductor 504, the description of the conductor 404 is referred to. For the insulator 512, the description of the insulator 412 is referred to. For the semiconductor 506, the description of the semiconductor 406 is referred to. For the conductors 516a and 516b, the description of the conductors 416a and 416b is referred to. For the insulator 518, the description of the insulator 402 is referred to.

### <Structure of Oxide Semiconductor>

The structure of an oxide semiconductor is described below.

Oxide semiconductors are classified roughly into a single-crystal oxide semiconductor and a non-single-crystal oxide semiconductor. The non-single-crystal oxide semiconductor includes any of a c-axis-aligned crystalline oxide semiconductor (CAAC-OS), a polycrystalline oxide semiconductor, a microcrystalline oxide semiconductor, an amorphous oxide semiconductor, and the like.

First, a CAAC-OS is described.

The CAAC-OS is an oxide semiconductor having a plurality of c-axis aligned crystal parts.

With a transmission electron microscope (TEM), a combined analysis image (high-resolution TEM image) of a bright-field image and a diffraction pattern of the CAAC-OS is observed, and a plurality of crystal parts can be clearly observed. However, in the high-resolution TEM image, a boundary between crystal parts, that is, a grain boundary is not clearly observed. Thus, in the CAAC-OS, a reduction in electron mobility due to the grain boundary is less likely to occur.

According to the high-resolution cross-sectional TEM image of the CAAC-OS observed in a direction substantially parallel to a sample surface, metal atoms are arranged in a layered manner in the crystal parts. Each metal atom layer reflects unevenness of a surface over which the CAAC-OS is formed (hereinafter a surface over which the CAAC-OS is formed is referred to as a formation surface) or a top surface of the CAAC-OS, and is arranged parallel to the formation surface or the top surface of the CAAC-OS.

In the high-resolution plan-view TEM image of the CAAC-OS observed in a direction substantially perpendicular to the sample surface, metal atoms arranged in a triangular or hexagonal configuration are seen in the crystal parts. However, there is no regularity of arrangement of metal atoms between different crystal parts.

A CAAC-OS is subjected to structural analysis with an X-ray diffraction (XRD) apparatus. For example, when the CAAC-OS including an InGaZnO₄ crystal is analyzed by an out-of-plane method, a peak appears frequently at a diffraction angle (2θ) of around 31°. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

When the CAAC-OS with an InGaZnO₄ crystal is analyzed by an out-of-plane method, a peak may also be observed at 2θ of around 36° as well as at 2θ of around 31°. The peak at 2θ of around 36° indicates that a crystal having no c-axis alignment is included in part of the CAAC-OS. It is preferable that in the CAAC-OS, a peak appear at 2θ of around 31° and a peak not appear at 2θ of around 36°.

The CAAC-OS is an oxide semiconductor having low impurity concentration. The impurity is an element other than the main components of the oxide semiconductor, such as hydrogen, carbon, silicon, or a transition metal element. In particular, an element that has higher bonding strength to oxygen than a metal element included in the oxide semiconductor, such as silicon, disturbs the atomic arrangement of the oxide semiconductor by depriving the oxide semiconductor of oxygen and causes a decrease in crystallinity. A heavy metal such as iron or nickel, argon, carbon dioxide, or the like has a large atomic radius (molecular radius), and thus disturbs the atomic arrangement of the oxide semiconductor and causes a decrease in crystallinity when it is contained in the oxide semiconductor. Note that the impurity contained in the oxide semiconductor might serve as a carrier trap or a carrier generation source.

The CAAC-OS is an oxide semiconductor having a low density of defect states. In some cases, oxygen vacancies in the oxide semiconductor serve as carrier traps or serve as carrier generation sources when hydrogen is captured therein.

The state in which the impurity concentration is low and the density of defect states is low (the number of oxygen vacancies is small) is referred to as a “highly purified intrinsic” or “substantially highly purified intrinsic” state. A highly purified intrinsic or substantially highly purified intrinsic oxide semiconductor has few carrier generation sources, and thus can have a low carrier density. Thus, a transistor including the oxide semiconductor rarely has negative threshold voltage (rarely has normally-on characteristics). The highly purified intrinsic or substantially highly purified intrinsic oxide semiconductor has few carrier traps. Consequently, the transistor including the oxide semiconductor has little variation in electrical characteristics and high reliability. Electric charge trapped by the carrier traps in the oxide semiconductor takes a long time to be released and might behave like fixed electric charge. Thus, the transistor including the oxide semiconductor having high impurity concentration and a high density of defect states has unstable electrical characteristics in some cases.

With the use of the CAAC-OS in a transistor, variation in the electrical characteristics of the transistor due to irradiation with visible light or ultraviolet light is small.

Next, a microcrystalline oxide semiconductor is described.

In a high-resolution TEM image of a microcrystalline oxide semiconductor, there are a region where a crystal part is observed and a region where a crystal part is not clearly observed. In most cases, a crystal part in the microcrystalline oxide semiconductor ranges from 1 nm to 100 nm, or from 1 nm to 10 nm. A microcrystal with a size in the range of 1 nm to 10 nm or of 1 nm to 3 nm is specifically referred to as nanocrystal (nc). An oxide semiconductor including nanocrystal is referred to as a nanocrystalline oxide semiconductor (nc-OS). In a high-resolution TEM image of the nc-OS, a grain boundary cannot be found clearly in some cases.

In the nc-OS, a microscopic region (e.g., a region with a size ranging from 1 nm to 10 nm, in particular, from 1 nm to 3 nm) has a periodic atomic order. There is no regularity of crystal orientation between different crystal parts in the nc-OS. Thus, the orientation of the whole film is not observed. Consequently, in some cases, the nc-OS cannot be distinguished from an amorphous oxide semiconductor depending on an analysis method. For example, when the nc-OS is subjected to structural analysis by an out-of-plane method with an XRD apparatus using an X-ray having a diameter larger than that of a crystal part, a peak showing a crystal plane does not appear. A diffraction pattern like a halo pattern appears in a selected-area electron diffraction pattern of the nc-OS obtained by using an electron beam having a probe diameter larger than the diameter of a crystal part (e.g., having a probe diameter of 50 nm or larger). Meanwhile, spots are shown in a nanobeam electron diffraction pattern of the nc-OS obtained by using an electron beam having a probe diameter close to or smaller than the diameter of a crystal part. Furthermore, in a nanobeam electron diffraction pattern of the nc-OS, regions with high luminance in a circular (ring) pattern are sometimes shown. Also in a nanobeam electron diffraction pattern of the nc-OS, a plurality of spots are sometimes shown in a ring-like region.

The nc-OS is an oxide semiconductor that has higher regularity than an amorphous oxide semiconductor, and therefore has a lower density of defect states than an amorphous oxide semiconductor. However, there is no regularity of crystal orientation between different crystal parts in the nc-OS; hence, the nc-OS has a higher density of defect states than the CAAC-OS.

Next, an amorphous oxide semiconductor is described.

The amorphous oxide semiconductor has disordered atomic arrangement and no crystal part. An example of the amorphous oxide semiconductor is an oxide semiconductor with a non-crystalline state like quartz.

In a high-resolution TEM image of the amorphous oxide semiconductor, crystal parts cannot be found.

When the amorphous oxide semiconductor is subjected to structural analysis by an out-of-plane method with an XRD apparatus, a peak showing a crystal plane does not appear. A halo pattern is shown in an electron diffraction pattern of the amorphous oxide semiconductor. Furthermore, a halo pattern is shown but a spot is not shown in a nanobeam electron diffraction pattern of the amorphous oxide semiconductor.

Note that an oxide semiconductor may have a structure with physical properties between the nc-OS and the amorphous oxide semiconductor. The oxide semiconductor having such a structure is specifically referred to as an amorphous-like oxide semiconductor (a-like OS).

In a high-resolution TEM image of the a-like OS, a void may be seen. Furthermore, in the high-resolution TEM image, there are a region where a crystal part is clearly observed and a region where a crystal part is not observed. In the a-like OS, crystallization occurs by a slight amount of electron beam used for TEM observation and growth of the crystal part is found in some cases. In contrast, crystallization due to a slight amount of electron beam used for TEM observation is hardly observed in the nc-OS having good quality.

Note that the crystal part size in the a-like OS and the nc-OS can be measured using high-resolution TEM images. For example, an InGaZnO₄ crystal has a layered structure in which two Ga—Zn—O layers are included between In—O layers. A unit cell of the InGaZnO₄ crystal has a structure in which nine layers of three In—O layers and six Ga—Zn—O layers are layered in the c-axis direction. Thus, the spacing between these adjacent layers is substantially equivalent to the lattice spacing (also referred to as d value) on the (009) plane, and is 0.29 nm according to crystal structure analysis. Consequently, focusing on the lattice fringes in the high-resolution TEM image, lattice fringes with a spacing ranging from 0.28 nm to 0.30 nm each correspond to the a-b plane of the InGaZnO₄ crystal.

The density of an oxide semiconductor might vary depending on its structure. For example, when the composition of an oxide semiconductor becomes clear, the structure of the oxide semiconductor can be estimated from a comparison between the density of the oxide semiconductor and the density of a single crystal oxide semiconductor having the same composition as the oxide semiconductor. For instance, the density of an a-like OS is 78.6% or higher and lower than 92.3% of the density of the single crystal oxide semiconductor. In addition, for example, the density of an nc-OS or a CAAC-OS is 92.3% or higher and lower than 100% of the density of the single crystal oxide semiconductor. Note that it is difficult to deposit an oxide semiconductor whose density is lower than 78% of the density of the single crystal oxide semiconductor.

A specific example of the above is described. For example, in an oxide semiconductor with an atomic ratio of In:Ga:Zn=1:1:1, the density of single crystal InGaZnO₄ with a rhombohedral crystal structure is 6.357 g/cm³. Thus, for example, the density of an a-like OS with an atomic ratio of In:Ga:Zn=1:1:1 is higher than or equal to 5.0 g/cm³ and lower than 5.9 g/cm³. Moreover, for example, the density of an nc-OS or a CAAC-OS with an atomic ratio of In:Ga:Zn=1:1:1 is higher than or equal to 5.9 g/cm³ and lower than 6.3 g/cm³.

Note that there is a possibility that an oxide semiconductor having a certain composition cannot exist in a single crystal structure. In such a case, by combining single crystals with different compositions at a given proportion, it is possible to calculate density that corresponds to the density of a single crystal with a desired composition. The density of the single crystal with a desired composition may be calculated using weighted average with respect to the combination ratio of the single crystals with different compositions. Note that it is preferable to combine as few kinds of single crystals as possible for density calculation.

Note that an oxide semiconductor may be a stacked film including two or more films of an amorphous oxide semiconductor, an a-like OS, a microcrystalline oxide semiconductor, and a CAAC-OS, for example.

### <Semiconductor Device>

An example of a semiconductor device of one embodiment of the present invention is shown below.

### <Circuit>

An example of a circuit including a transistor of one embodiment of the present invention is shown below.

### [CMOS Inverter]

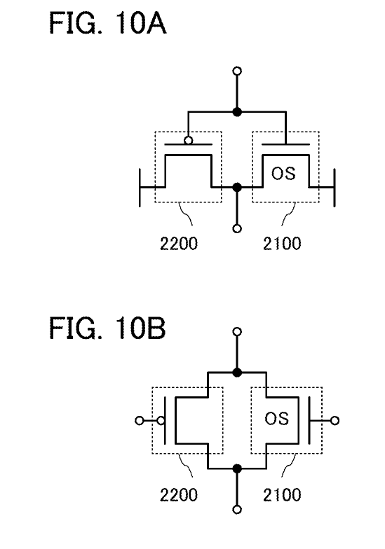

A circuit diagram in FIG. 10A shows a configuration of a so-called CMOS inverter in which the p-channel transistor 2200 and the n-channel transistor 2100 are connected to each other in series and in which gates of them are connected to each other.

### [CMOS Analog Switch]

A circuit diagram in FIG. 10B shows a configuration in which sources of the transistors 2100 and 2200 are connected to each other and drains of the transistors 2100 and 2200 are connected to each other. With such a configuration, the transistors can function as a so-called CMOS analog switch.

### [Memory Device Example]

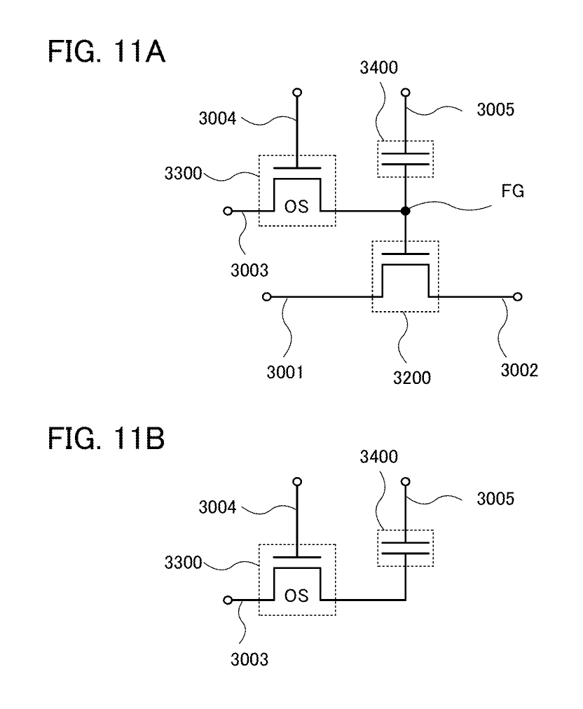

An example of a semiconductor device (memory device) which includes the transistor of one embodiment of the present invention, which can retain stored data even when not powered, and which has an unlimited number of write cycles is shown in FIGS. 11A and 11B.

The semiconductor device illustrated in FIG. 11A includes a transistor 3200 using a first semiconductor, a transistor 3300 using a second semiconductor, and a capacitor 3400. Note that any of the above-described transistors can be used as the transistor 3300.

The transistor 3300 is a transistor using an oxide semiconductor. Since the off-state current of the transistor 3300 is low, stored data can be retained for a long period at a predetermined node of the semiconductor device. In other words, power consumption of the semiconductor device can be reduced because refresh operation becomes unnecessary or the frequency of refresh operation can be extremely low.

In FIG. 11A, a first wiring 3001 is electrically connected to a source of the transistor 3200. A second wiring 3002 is electrically connected to a drain of the transistor 3200. A third wiring 3003 is electrically connected to one of the source and the drain of the transistor 3300. A fourth wiring 3004 is electrically connected to the gate of the transistor 3300. The gate of the transistor 3200 and the other of the source and the drain of the transistor 3300 are electrically connected to the one electrode of the capacitor 3400. A fifth wiring 3005 is electrically connected to the other electrode of the capacitor 3400.

The semiconductor device in FIG. 11A has a feature that the potential of the gate of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to a node FG where the gate of the transistor 3200 and the one electrode of the capacitor 3400 are electrically connected to each other. That is, a predetermined charge is supplied to the gate of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, so that the transistor 3300 is turned off. Thus, the charge is held at the node FG (retaining).

Since the off-state current of the transistor 3300 is extremely low, the charge of the node FG is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the node FG. This is because in the case of using an n-channel transistor as the transistor 3200, an apparent threshold voltage Vₜₕ_{_{—}}_{H} at the time when the high-level charge is given to the gate of the transistor 3200 is lower than an apparent threshold voltage Vₜₕ_{_{—}}_{L} at the time when the low-level charge is given to the gate of the transistor 3200. Here, an apparent threshold voltage refers to the potential of the fifth wiring 3005 which is needed to turn on the transistor 3200. Thus, the potential of the fifth wiring 3005 is set to a potential V₀ which is between Vₜₕ_{_{—}}_{H} and Vₜₕ_{_{—}}_{L}, whereby charge supplied to the node FG can be determined. For example, in the case where the high-level charge is supplied to the node FG in writing and the potential of the fifth wiring 3005 is V₀ (>Vₜₕ_{_{—}}_{H}), the transistor 3200 is turned on. On the other hand, in the case where the low-level charge is supplied to the node FG in writing, even when the potential of the fifth wiring 3005 is V₀ (<Vₜₕ_{_{—}}_{L}), the transistor 3200 remains off. Thus, the data retained in the node FG can be read by determining the potential of the second wiring 3002.

Note that in the case where memory cells are arrayed, it is necessary that data of a desired memory cell is read in read operation. In the case where data of the other memory cells is not read, the fifth wiring 3005 may be supplied with a potential at which the transistor 3200 is turned off regardless of the charge supplied to the node FG, that is, a potential lower than Vₜₕ_{_{—}}_{H}. Alternatively, the fifth wiring 3005 may be supplied with a potential at which the transistor 3200 is turned on regardless of the charge supplied to the node FG, that is, a potential higher than Vₜₕ_{_{—}}_{L}.

The semiconductor device in FIG. 11B differs from the semiconductor device in FIG. 11A in that the transistor 3200 is not provided. Also in this case, writing and retaining operation of data can be performed in a manner similar to that of the semiconductor device in FIG. 11A.

Reading of data in the semiconductor device in FIG. 11B is described. When the transistor 3300 is turned on, the third wiring 3003 which is in a floating state and the capacitor 3400 are electrically connected to each other, and the charge is redistributed between the third wiring 3003 and the capacitor 3400. As a result, the potential of the third wiring 3003 is changed. The amount of change in potential of the third wiring 3003 varies depending on the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 in the case of retaining the potential V₁ (=(C_{B}×V_{B0}+C×V₁)/(C_{B}+C)) is higher than the potential of the third wiring 3003 in the case of retaining the potential V₀ (=(C_{B}×V_{B0}+C×V₀)/(C_{B}+C)).

Then, by comparing the potential of the third wiring 3003 with a predetermined potential, data can be read.

In this case, a transistor including the first semiconductor may be used for a driver circuit for driving a memory cell, and a transistor including the second semiconductor may be stacked over the driver circuit as the transistor 3300.

When including a transistor using an oxide semiconductor and having an extremely low off-state current, the semiconductor device described above can retain stored data for a long time. In other words, power consumption of the semiconductor device can be reduced because refresh operation becomes unnecessary or the frequency of refresh operation can be extremely low. Moreover, stored data can be retained for a long time even when power is not supplied (note that a potential is preferably fixed).

In the semiconductor device, high voltage is not needed for writing data and deterioration of elements is less likely to occur. Unlike in a conventional nonvolatile memory, for example, it is not necessary to inject and extract electrons into and from a floating gate; thus, a problem such as deterioration of an insulator is not caused. That is, the semiconductor device of one embodiment of the present invention does not have a limit on the number of times data can be rewritten, which is a problem of a conventional nonvolatile memory, and the reliability thereof is drastically improved. Furthermore, data is written depending on the state of the transistor (on or off), whereby high-speed operation can be achieved.

### <CPU>

A CPU including a semiconductor device such as any of the above-described transistors or the above-described memory device is described below.

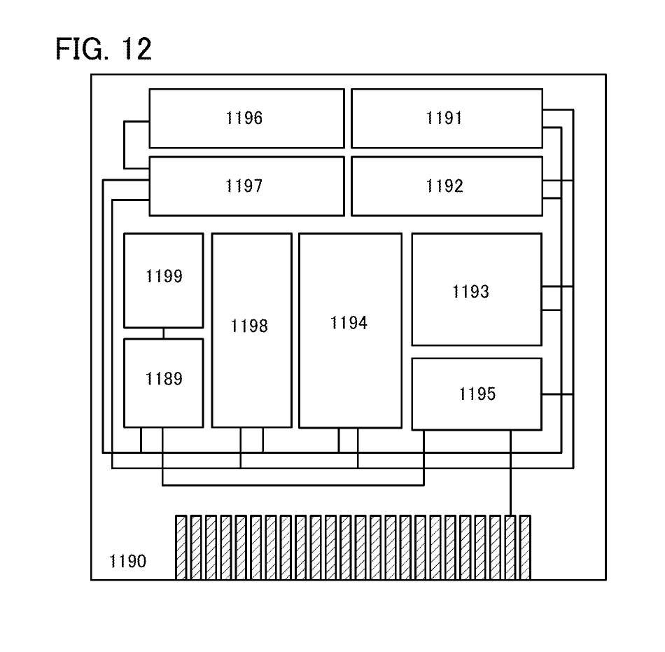

FIG. 12 is a block diagram illustrating a configuration example of a CPU including any of the above-described transistors as a component.

The CPU illustrated in FIG. 12 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface 1198, a rewritable ROM 1199, and a ROM interface 1189. A semiconductor substrate, an SOI substrate, a glass substrate, or the like is used as the substrate 1190. The ROM 1199 and the ROM interface 1189 may be provided over a separate chip. Needless to say, the CPU in FIG. 12 is just an example in which the configuration has been simplified, and an actual CPU may have a variety of configurations depending on the application. For example, the CPU may have the following configuration: a structure including the CPU illustrated in FIG. 12 or an arithmetic circuit is considered as one core; a plurality of the cores are included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal based on a reference clock signal, and supplies the internal clock signal to the above circuits.

In the CPU illustrated in FIG. 12, a memory cell is provided in the register 1196. For the memory cell of the register 1196, any of the above-described transistors, the above-described memory device, or the like can be used.

In the CPU illustrated in FIG. 12, the register controller 1197 selects operation of retaining data in the register 1196 in accordance with an instruction from the ALU 1191. That is, the register controller 1197 selects whether data is retained by a flip-flop or by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of power supply voltage to the memory cell in the register 1196 can be stopped.

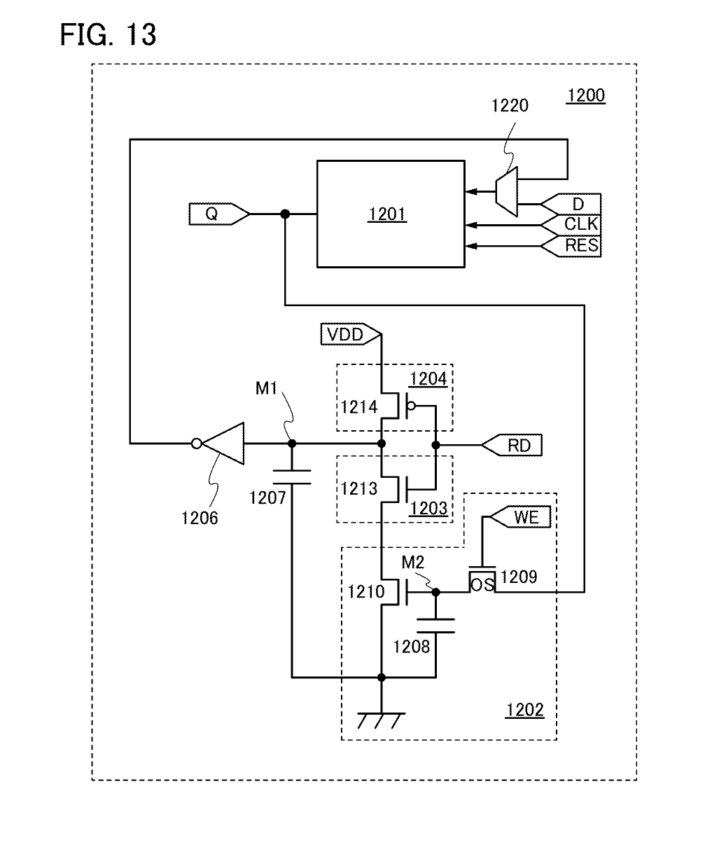

FIG. 13 is an example of a circuit diagram of a memory element 1200 that can be used as the register 1196. The memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the above-described memory device can be used as the circuit 1202. When supply of a power supply voltage to the memory element 1200 is stopped, GND (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a line which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a line which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the line which can supply a low power supply potential (e.g., a GND line). The other of the pair of electrodes of the capacitor 1208 can be supplied with a constant potential. For example, the other of the pair of electrodes of the capacitor 1208 can be supplied with the low power supply potential (e.g., GND) or the high power supply potential (e.g., VDD). The other of the pair of electrodes of the capacitor 1208 is electrically connected to the line which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to the gate of the transistor 1209. As for each of the switch 1203 and the switch 1204, a conduction state or a non-conduction state between the first terminal and the second terminal is selected by the control signal RD which is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 13 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 13, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 13, the transistors included in the memory element 1200 except for the transistor 1209 can each be a transistor in which a channel is formed in a film formed using a semiconductor other than an oxide semiconductor or in the substrate 1190. For example, the transistor can be a transistor whose channel is formed in a silicon film or a silicon substrate. Alternatively, all the transistors in the memory element 1200 may be a transistor in which a channel is formed in an oxide semiconductor. Further alternatively, in the memory element 1200, a transistor in which a channel is formed in an oxide semiconductor may be included besides the transistor 1209, and a transistor in which a channel is formed in a layer formed using a semiconductor other than an oxide semiconductor or in the substrate 1190 can be used for the rest of the transistors.

As the circuit 1201 in FIG. 13, for example, a flip-flop circuit can be used. As the logic element 1206, for example, an inverter or a clocked inverter can be used.

In a period during which the memory element 1200 is not supplied with the power supply voltage, the semiconductor device of one embodiment of the present invention can retain data stored in the circuit 1201 by the capacitor 1208 which is provided in the circuit 1202.

The off-state current of a transistor in which a channel is formed in an oxide semiconductor is extremely low. For example, the off-state current of a transistor in which a channel is formed in an oxide semiconductor is significantly lower than that of a transistor in which a channel is formed in silicon having crystallinity. Thus, when the transistor is used as the transistor 1209, a signal held in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the above-described memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the signal retained by the capacitor 1208 can be converted into the one corresponding to the state (the on state or the off state) of the transistor 1210 to be read from the circuit 1202. Consequently, an original signal can be accurately read even when a potential corresponding to the signal retained by the capacitor 1208 varies to some degree.

By applying the above-described memory element 1200 to a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Therefore, the power supply can be stopped even for a short time in the processor or one or a plurality of logic circuits included in the processor, resulting in lower power consumption.

Although the memory element 1200 is used in a CPU, the memory element 1200 can also be used in an LSI such as a digital signal processor (DSP), a custom LSI, or a programmable logic device (PLD), and a radio frequency identification (RF-ID).

### <Display Device>

The following shows configuration examples of a display device of one embodiment of the present invention.

### Configuration Example

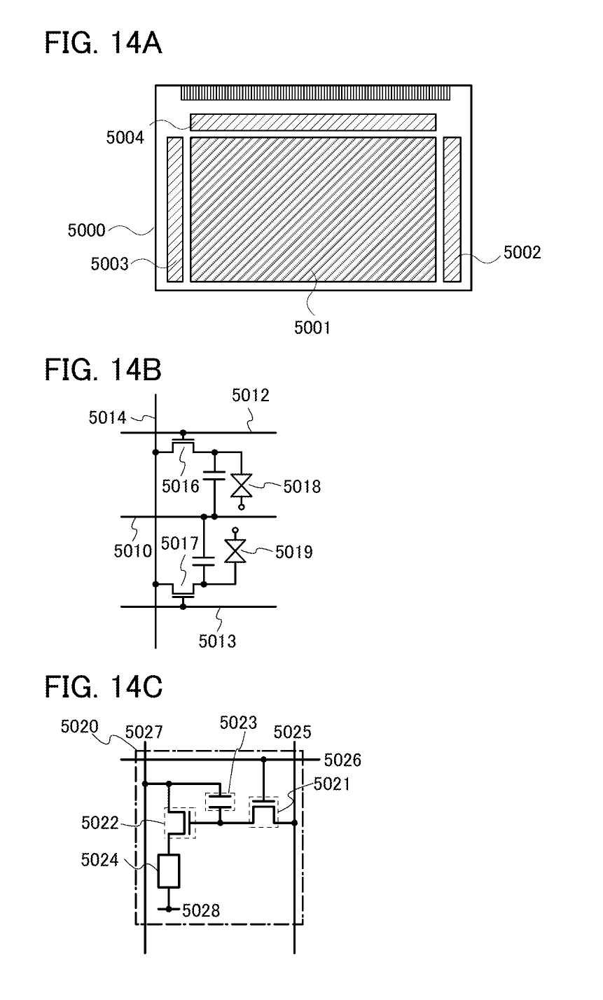

FIG. 14A is a top view of a display device of one embodiment of the present invention. FIG. 14B illustrates a pixel circuit where a liquid crystal element is used for a pixel of a display device of one embodiment of the present invention. FIG. 14C illustrates a pixel circuit where an organic EL element is used for a pixel of a display device of one embodiment of the present invention.

Any of the above-described transistors can be used as a transistor used for the pixel. Here, an example in which an n-channel transistor is used is shown. Note that a transistor manufactured through the same steps as the transistor used for the pixel may be used for a driver circuit. Thus, by using any of the above-described transistors for a pixel or a driver circuit, the display device can have high display quality and/or high reliability.

FIG. 14A illustrates an example of an active matrix display device. A pixel portion 5001, a first scan line driver circuit 5002, a second scan line driver circuit 5003, and a signal line driver circuit 5004 are provided over a substrate 5000 in the display device. The pixel portion 5001 is electrically connected to the signal line driver circuit 5004 through a plurality of signal lines and is electrically connected to the first scan line driver circuit 5002 and the second scan line driver circuit 5003 through a plurality of scan lines. Pixels including display elements are provided in respective regions divided by the scan lines and the signal lines. The substrate 5000 of the display device is electrically connected to a timing control circuit (also referred to as a controller or a control IC) through a connection portion such as a flexible printed circuit (FPC).

The first scan line driver circuit 5002, the second scan line driver circuit 5003, and the signal line driver circuit 5004 are formed over the substrate 5000 where the pixel portion 5001 is formed. Therefore, a display device can be manufactured at cost lower than that in the case where a driver circuit is separately formed. Furthermore, in the case where a driver circuit is separately formed, the number of wiring connections is increased. By providing the driver circuit over the substrate 5000, the number of wiring connections can be reduced. Accordingly, the reliability and/or yield can be improved.

### [Liquid Crystal Display Device]

FIG. 14B illustrates an example of a circuit configuration of the pixel. Here, a pixel circuit which is applicable to a pixel of a VA liquid crystal display device, or the like is illustrated.

This pixel circuit can be applied to a structure in which one pixel includes a plurality of pixel electrodes. The pixel electrodes are connected to different transistors, and the transistors can be driven with different gate signals. Accordingly, signals applied to individual pixel electrodes in a multi-domain pixel can be controlled independently.

A gate wiring 5012 of a transistor 5016 and a gate wiring 5013 of a transistor 5017 are separated so that different gate signals can be supplied thereto. In contrast, a source or drain electrode 5014 functioning as a data line is shared by the transistors 5016 and 5017. Any of the above-described transistors can be used as appropriate as each of the transistors 5016 and 5017. Thus, the liquid crystal display device can have high display quality and/or high reliability.

A first pixel electrode is electrically connected to the transistor 5016 and a second pixel electrode is electrically connected to the transistor 5017. The first pixel electrode and the second pixel electrode are separated. Shapes of the first pixel electrode and the second pixel electrode are not especially limited. For example, the first pixel electrode may have a V-like shape.

A gate electrode of the transistor 5016 is electrically connected to the gate wiring 5012, and a gate electrode of the transistor 5017 is electrically connected to the gate wiring 5013. When different gate signals are supplied to the gate wiring 5012 and the gate wiring 5013, operation timings of the transistor 5016 and the transistor 5017 can be varied. As a result, alignment of liquid crystals can be controlled.

Furthermore, a capacitor may be formed using a capacitor wiring 5010, a gate insulator functioning as a dielectric, and a capacitor electrode electrically connected to the first pixel electrode or the second pixel electrode.

The pixel structure is a multi-domain structure in which a first liquid crystal element 5018 and a second liquid crystal element 5019 are provided in one pixel. The first liquid crystal element 5018 includes the first pixel electrode, a counter electrode, and a liquid crystal layer therebetween. The second liquid crystal element 5019 includes the second pixel electrode, a counter electrode, and a liquid crystal layer therebetween.

Note that a pixel circuit in the display device of one embodiment of the present invention is not limited to that shown in FIG. 14B. For example, a switch, a resistor, a capacitor, a transistor, a sensor, a logic circuit, or the like may be added to the pixel circuit shown in FIG. 14B.

### [Organic EL Display Device]

FIG. 14C illustrates another example of a circuit configuration of the pixel. Here, a pixel structure of a display device using an organic EL element is shown.

In an organic EL element, by application of voltage to a light-emitting element, electrons are injected from one of a pair of electrodes included in the organic EL element and holes are injected from the other of the pair of electrodes, into a layer containing a light-emitting organic compound; thus, a current flows. The electrons and holes are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 14C illustrates an example of a pixel circuit. Here, one pixel includes two n-channel transistors. Note that any of the above-described transistors can be used as the n-channel transistors. Furthermore, digital time grayscale driving can be employed for the pixel circuit.

The configuration of the applicable pixel circuit and operation of a pixel employing digital time grayscale driving will be described.

A pixel 5020 includes a switching transistor 5021, a driver transistor 5022, a light-emitting element 5024, and a capacitor 5023. A gate electrode of the switching transistor 5021 is connected to a scan line 5026, a first electrode (one of a source electrode and a drain electrode) of the switching transistor 5021 is connected to a signal line 5025, and a second electrode (the other of the source electrode and the drain electrode) of the switching transistor 5021 is connected to a gate electrode of the driver transistor 5022. The gate electrode of the driver transistor 5022 is connected to a power supply line 5027 through the capacitor 5023, a first electrode of the driver transistor 5022 is connected to the power supply line 5027, and a second electrode of the driver transistor 5022 is connected to a first electrode (a pixel electrode) of the light-emitting element 5024. A second electrode of the light-emitting element 5024 corresponds to a common electrode 5028. The common electrode 5028 is electrically connected to a common potential line provided over the same substrate.

As each of the switching transistor 5021 and the driver transistor 5022, any of the above-described transistors can be used as appropriate. In this manner, an organic EL display device having high display quality and/or high reliability can be provided.

The potential of the second electrode (the common electrode 5028) of the light-emitting element 5024 is set to be a low power supply potential. Note that the low power supply potential is lower than a high power supply potential supplied to the power supply line 5027. For example, the low power supply potential can be GND, 0 V, or the like. The high power supply potential and the low power supply potential are set to be higher than or equal to the forward threshold voltage of the light-emitting element 5024, and the difference between the potentials is applied to the light-emitting element 5024, whereby a current is supplied to the light-emitting element 5024, leading to light emission. The forward voltage of the light-emitting element 5024 refers to a voltage at which a desired luminance is obtained, and includes at least forward threshold voltage.

Note that gate capacitance of the driver transistor 5022 may be used as a substitute for the capacitor 5023 in some cases, so that the capacitor 5023 can be omitted. The gate capacitance of the driver transistor 5022 may be formed between the channel formation region and the gate electrode.

Next, a signal input to the driver transistor 5022 is described. In the case of a voltage-input voltage driving method, a video signal for turning on or off the driver transistor 5022 is input to the driver transistor 5022. In order for the driver transistor 5022 to operate in a linear region, voltage higher than the voltage of the power supply line 5027 is applied to the gate electrode of the driver transistor 5022. Note that voltage higher than or equal to voltage which is the sum of power supply line voltage and the threshold voltage Vₜₕ of the driver transistor 5022 is applied to the signal line 5025.

In the case of performing analog grayscale driving, a voltage higher than or equal to a voltage which is the sum of the forward voltage of the light-emitting element 5024 and the threshold voltage Vₜₕ of the driver transistor 5022 is applied to the gate electrode of the driver transistor 5022. A video signal by which the driver transistor 5022 is operated in a saturation region is input, so that a current is supplied to the light-emitting element 5024. In order for the driver transistor 5022 to operate in a saturation region, the potential of the power supply line 5027 is set higher than the gate potential of the driver transistor 5022. When an analog video signal is used, it is possible to supply a current to the light-emitting element 5024 in accordance with the video signal and perform analog grayscale driving.

Note that in the display device of one embodiment of the present invention, a pixel configuration is not limited to that shown in FIG. 14C. For example, a switch, a resistor, a capacitor, a sensor, a transistor, a logic circuit, or the like may be added to the pixel circuit shown in FIG. 14C.

In the case where any of the above-described transistors is used for the circuit shown in FIGS. 14A to 14C, the source electrode (the first electrode) is electrically connected to the low potential side and the drain electrode (the second electrode) is electrically connected to the high potential side. Furthermore, the potential of the first gate electrode may be controlled by a control circuit or the like and the potential described above as an example, e.g., a potential lower than the potential applied to the source electrode, may be input to the second gate electrode.

For example, in this specification and the like, a display element, a display device which is a device including a display element, a light-emitting element, and a light-emitting device which is a device including a light-emitting element can employ various modes or can include various elements. The display element, the display device, the light-emitting element, or the light-emitting device includes at least one of an electroluminescence (EL) element (e.g., an EL element including organic and inorganic materials, an organic EL element, or an inorganic EL element), an LED (e.g., a white LED, a red LED, a green LED, or a blue LED), a transistor (a transistor that emits light depending on current), an electron emitter, a liquid crystal element, electronic ink, an electrophoretic element, a grating light valve (GLV), a plasma display panel (PDP), a display element using micro electro mechanical system (MEMS), a digital micromirror device (DMD), a digital micro shutter (DMS), an interferometric modulator display (IMOD) element, a MEMS shutter display element, an optical-interference-type MEMS display element, an electrowetting element, a piezoelectric ceramic display, a display element including a carbon nanotube, and the like. Other than the above, a display medium whose contrast, luminance, reflectance, transmittance, or the like is changed by an electrical or magnetic effect may be included. Note that examples of a display device including an EL element include an EL display. Examples of a display device having an electron emitter include a field emission display (FED), an SED-type flat panel display (SED: surface-conduction electron-emitter display), and the like. Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). Display devices having electronic ink or electrophoretic elements include electronic paper and the like. In the case of a transflective liquid crystal display or a reflective liquid crystal display, some of or all of pixel electrodes function as reflective electrodes. For example, some or all of pixel electrodes are formed to contain aluminum, silver, or the like. In such a case, a memory circuit such as an SRAM can be provided under the reflective electrodes. Thus, the power consumption can be further reduced. Note that in the case of using an LED, graphene or graphite may be provided under an electrode or a nitride semiconductor of the LED. Graphene or graphite may be a multilayer film in which a plurality of layers are stacked. As described above, provision of graphene or graphite enables easy formation of a nitride semiconductor thereover, such as an n-type GaN semiconductor including crystals. Furthermore, a p-type GaN semiconductor including crystals or the like can be provided thereover, and thus the LED can be formed. Note that MN may be provided between the n-type GaN semiconductor including crystals and graphene or graphite. The GaN semiconductors included in the LED may be formed by MOCVD. Note that when the graphene is provided, the GaN semiconductors included in the LED can also be formed by a sputtering method.

### <Electronic Device>

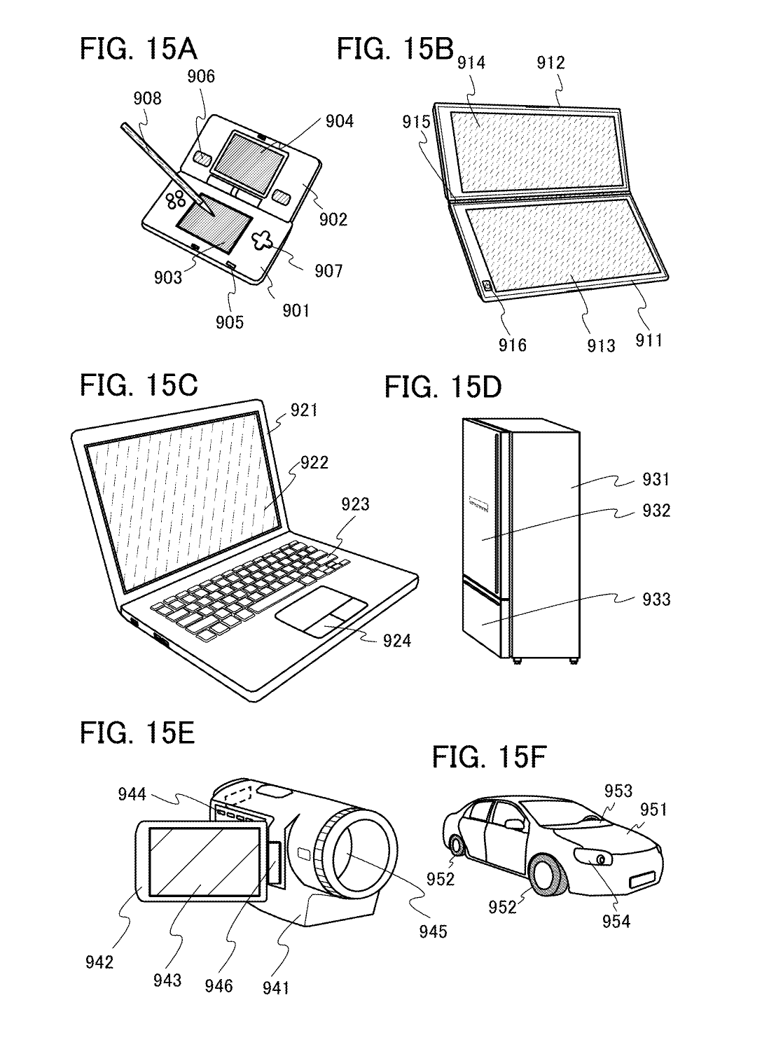

The semiconductor device of one embodiment of the present invention can be used for display devices, personal computers, or image reproducing devices provided with recording media (typically, devices which reproduce the content of recording media such as digital versatile discs (DVDs) and have displays for displaying the reproduced images). Other examples of electronic devices that can be equipped with the semiconductor device of one embodiment of the present invention are mobile phones, game machines including portable game consoles, portable data terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 15A to 15F illustrate specific examples of these electronic device.

FIG. 15A illustrates a portable game console including a housing 901, a housing 902, a display portion 903, a display portion 904, a microphone 905, a speaker 906, an operation key 907, a stylus 908, and the like. Although the portable game console in FIG. 15A has the two display portions 903 and 904, the number of display portions included in a portable game console is not limited to this.

FIG. 15B illustrates a portable data terminal including a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. An image on the first display portion 913 may be switched in accordance with the angle at the joint 915 between the first housing 911 and the second housing 912. A display device with a position input function may be used as at least one of the first display portion 913 and the second display portion 914. Note that the position input function can be added by providing a touch panel in a display device. Alternatively, the position input function can be added by providing a photoelectric conversion element called a photosensor in a pixel portion of a display device.

FIG. 15C illustrates a laptop personal computer, which includes a housing 921, a display portion 922, a keyboard 923, a pointing device 924, and the like.

FIG. 15D illustrates an electric refrigerator-freezer, which includes a housing 931, a door for a refrigerator 932, a door for a freezer 933, and the like.

FIG. 15E illustrates a video camera, which includes a first housing 941, a second housing 942, a display portion 943, operation keys 944, a lens 945, a joint 946, and the like. The operation keys 944 and the lens 945 are provided for the first housing 941, and the display portion 943 is provided for the second housing 942. The first housing 941 and the second housing 942 are connected to each other with the joint 946, and the angle between the first housing 941 and the second housing 942 can be changed with the joint 946. Images displayed on the display portion 943 may be switched in accordance with the angle at the joint 946 between the first housing 941 and the second housing 942.

FIG. 15F illustrates an automobile including a car body 951, wheels 952, a dashboard 953, lights 954, and the like.

This application is based on Japanese Patent Application serial no. 2014-139002 filed with Japan Patent Office on Jul. 4, 2014, the entire contents of which are hereby incorporated by reference.

What is claimed is:

1. A semiconductor device comprising:
a conductor;
an oxide semiconductor comprising a region overlapping the conductor; and
an insulator between the oxide semiconductor and the conductor,
wherein the oxide semiconductor comprises interface states at an interface between the oxide semiconductor and the insulator in the region,
wherein the interface states are positioned in a range of an energy value of the conduction band minimum to 0.2 eV in the oxide semiconductor, and
wherein a density of the interface states is lower than or equal to 1×10¹³ cm⁻².

2. The semiconductor device according to claim 1, wherein the density of the interface states is measured by a high-frequency C-V method.

3. The semiconductor device according to claim 2, wherein the high-frequency C-V method is performed in such a manner that an alternating voltage at 0.1 kHz or higher and 10 MHz or lower and a direct-current voltage are applied to the conductor.

4. The semiconductor device according to claim 1, wherein a thickness of the oxide semiconductor is greater than or equal to 1 nm and less than or equal to 200 nm.

5. The semiconductor device according to claim 1,
wherein the oxide semiconductor comprises an oxide containing at least one selected from indium, zinc and an element M, and
wherein the element M is aluminum, gallium, yttrium, or tin.

6. A semiconductor device comprising:
a transistor comprising:
a conductor film;
an oxide semiconductor film comprising a region overlapping the conductor film; and
an insulator film between the oxide semiconductor film and the conductor film,
wherein the oxide semiconductor film comprises interface states at an interface between the oxide semiconductor film and the insulator film in the region,
wherein the interface states are positioned in a range of an energy value of the conduction band minimum to 0.2 eV in the oxide semiconductor film, and
wherein a density of the interface states is lower than or equal to 1×10¹³ cm⁻².

7. The semiconductor device according to claim 6, wherein the density of the interface states is measured by a high-frequency C-V method.

8. The semiconductor device according to claim 7, wherein the high-frequency C-V method is performed in such a manner that an alternating voltage at 0.1 kHz or higher and 10 MHz or lower and a direct-current voltage are applied to the conductor film.

9. The semiconductor device according to claim 6, wherein a thickness of the oxide semiconductor film is greater than or equal to 1 nm and less than or equal to 200 nm.

10. The semiconductor device according to claim 6,
wherein the oxide semiconductor film comprises an oxide containing at least one selected from indium, zinc and an element M, and
wherein the element M is aluminum, gallium, yttrium, or tin.

11. A semiconductor device comprising:
a transistor comprising:
a conductor film;
an oxide semiconductor film comprising a region overlapping the conductor film; and
an insulator film between the oxide semiconductor film and the conductor film,
wherein the oxide semiconductor film comprises interface states at an interface between the oxide semiconductor film and the insulator film in the region,
wherein the interface states are positioned in a range of an energy value of the conduction band minimum to 0.2 eV in the oxide semiconductor film, and
wherein a density of the interface states is lower than or equal to 1×10¹³ cm⁻²,
wherein a method for estimating the density of the interface states comprises the steps of:
measuring actually measured C-V characteristics of the transistor by a high-frequency C-V method;
calculating calculated C-V characteristics of the transistor; and
estimating the density of the interface states by comparison of the actually measured C-V characteristics with the calculated C-V characteristics.

12. The semiconductor device according to claim 11, wherein the high-frequency C-V method is performed in such a manner that an alternating voltage at 0.1 kHz or higher and 10 MHz or lower and a direct-current voltage are applied to the conductor film.

13. The semiconductor device according to claim 11, wherein a thickness of the oxide semiconductor film is greater than or equal to 1 nm and less than or equal to 200 nm.

14. The semiconductor device according to claim 11,
wherein the oxide semiconductor film comprises an oxide containing at least one selected from indium, zinc and an element M, and
wherein the element M is aluminum, gallium, yttrium, or tin.
